(19) United States
(12) Patent Application Publication
(10) Pub. No.: US 2017/0038418 A1
(43) Pub. Date: Feb. 9, 2017

(54) METHOD FOR MONITORING DC LINK CAPACITANCE IN POWER CONVERTERS

(71) Applicant: ABB Schweiz AG, Baden (CH)

(72) Inventors: Piotr Lipnicki, Lublin (PL); Daniel Lewandowski, Krakow (PL)

(21) Appl. No.: 15/296,751

(22) Filed: Oct. 18, 2016

Related U.S. Application Data
(63) Continuation of application No. PCT/EP2015/000814, filed on Apr. 16, 2015.

(30) Foreign Application Priority Data
Apr. 29, 2014 (EP) 14460024.4

(51) Int. Cl. G01R 27/26; G08B 21/18; H02M 5/44

(52) U.S. Cl. CPC G01R 27/2605; H02M 5/44; G08B 21/182

(57) ABSTRACT

Method and apparatus for measuring current of phases a, b, c and voltage of the DC link; determining inverter switch states of the inverter and rectifier switch states of the rectifier for each phase a, b, c; generating a trigger signal when the value of the inverter switch states of the inverter for each phase a, b, c have an equal values and determining a triggered time duration for the trigger signal; determining the rectifier switch states of the rectifier for each phase a, b, c at the triggered time duration and calculation current of the phase a, b, c and voltage of the DC link at the triggered time duration; reconstructing the DC link current at the triggered time duration; calculating an indicator ERS for the DC link voltage at the triggered time duration; calculating a total DC link capacitance C and comparing it with the initial DC link capacitance.

The subject of the invention is a method for monitoring DC link capacitance in power converters which is useful in condition monitoring of electronic equipment.

### BACKGROUND OF THE INVENTION

Many of converters applications are being considered as critical for plant production process. Offering enhanced functionality in modern power converters is a way to gain a competitive advantage in worldwide market. One of the values to the customers comes from low cost condition monitoring of critical equipment and from optimized maintenance costs. DC link is one of the elements of power converters circuits. Although the designers pay a lot of attention when designing DC link, breakdowns and failures of the DC link can still happen. Unfortunately this means that the whole converter must be shutdown in emergency mode to be repaired. Nowadays, monitoring of the DC link is becoming one of the desired features from customer side, as well as from the converter manufacturer.

The ever-increasing demands for greater efficiency and reliability of power converters, force the introduction of novel methods for improving their performance. One of the ways is to provide a detailed condition monitoring features for the elements of the converter, ensuring tracking of entire device status. Assuring proper monitoring of the DC link capacitance level is one of the solutions for converter status determination. The capacitor deterioration usually manifests by an increase in ESR and decrease in an effective capacitance. Earlier detection of the ESR increase allows for preventive mitigation actions i.e. scheduling shutdown and repairs. Moreover it also helps with evaluation of the expected operational time until failure may happen. Preventing the growth of ESR values over a specified level provides maintaining the quality of converted power and protects the converter from DC-link failure.

There is known from patent US 2010/0295554 A1 a method and system for monitoring the condition of the capacitor arrangement of the DC-voltage intermediate circuit of a power electronics appliance, such as of a frequency converter, at the place of usage, in which method the discharge voltage over the capacitor arrangement as a function of time is measured, and in which method the intermediate circuit is pre-charged With a pre-determined DC voltage, the pre-charging is removed from the intermediate circuit, the voltage of the intermediate circuit is measured by sampling at regular intervals, the voltage drop as a function of time is determined on the basis of the measured voltage of the intermediate circuit, the capacitance or the relative change in it is determined on the basis of the voltage drop, the value of the determined capacitance or of the relative change in it is compared to a pre-determined limit value on the basis of the voltage drop, and the necessary condition monitoring procedure is performed when the value determined with the measurement reaches the pre-determined limit value or is close to it. The disadvantage of the method is the need for performing initial measurement of the discharge curve and performing the measurements each time before starting the converter, thus it cannot be used online continuously.

There is known from patent U.S. Pat. No. 6,381,158B1 a system and method for monitoring DC link capacitance in three level inverters where a signal is injected into a neutral point regulator of an inverter drive and the response to that injected signal is monitored as an indication of the capacitance of the inverter drive. The disadvantage of the method is the need of additional passive elements used for additional device which is responsible for signal injecting.

### SUMMARY OF THE INVENTION

The presented invention provides a diagnostic method for monitoring DC link in power converters according to claim 1.

The presented invention is advantageous relative to the previously described existing methods as it allows for monitoring of the DC link using less measurement devices inside the power converter, namely only DC link voltage measuring device is used. Moreover in the method according to the invention the calculation process is simplified and thus does not required a significant calculation power. Also by using synchronization with inverter switching signal further simplification in software by reducing algorithm complexity and in hardware by reducing number of elements is achieved, so the inventive method allows for saving time during monitoring DC link capacitance.

### BRIEF DESCRIPTION OF THE DRAWINGS

FIG. 1—is a picture of power converter equivalent system,

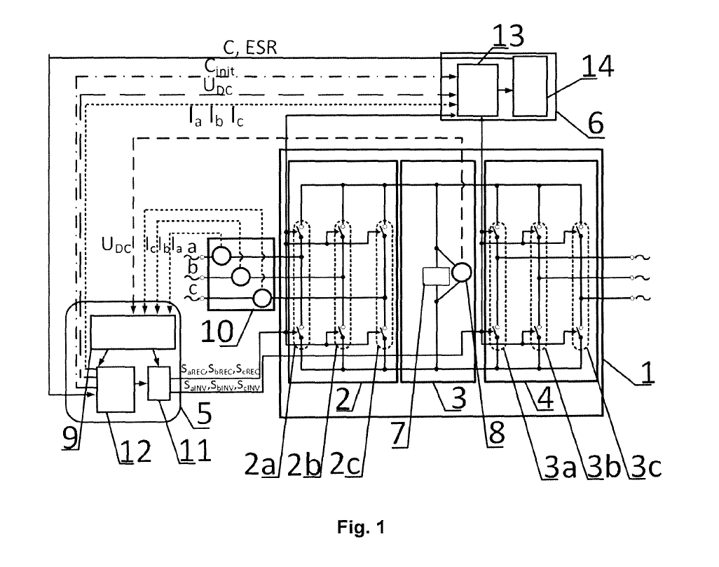

FIG. 2—is a diagram of operations performed for method for monitoring DC link in accordance with the invention,

FIG. 3—is an electrical scheme of basic DC link circuit,

FIG. 4—is a plot of measured parameters during time period for indicating consecutive triggering signals S_{TRIG},

FIG. 5—is a plot of measured current during time period for presenting the DC-link current reconstruction principle.

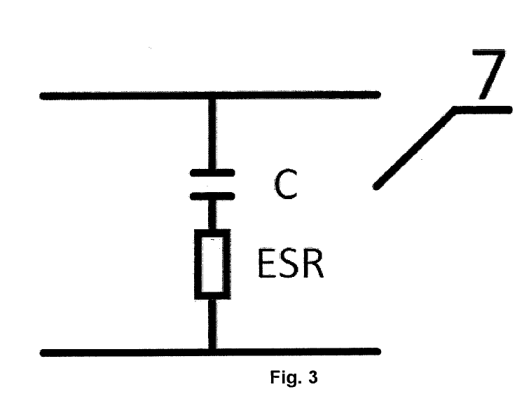

A power converter system comprises a power converter circuit 1 having a rectifying unit 2, a DC link unit 3, an inverter unit 4, and the power converter circuit 1 is connected with a converter control unit 5 and a DC link monitoring unit 6. The converter control unit 5 and the DC link monitoring unit 6 may be combined in single unit what is not presented in the drawing. The power converter circuit 1, the control unit 5 and DC link monitoring unit 6 are powered by three phase power supply lines a, b, c. The rectifying unit 2 has at least two solid state switches 2a, 2b, 2c, forming an inverter switching leg for each phase a, b, c, for converting the AC input voltage into DC output voltage. The solid-state switches of the rectifying unit 2 is one of the possible known kinds e.g. diodes, transistors, thyristors, etc. The DC link unit 3 includes at least one DC link circuit 7 and a DC link voltage measuring device 8. DC link circuit 7 comprises capacitor and an equivalent of series resistance ESR presented in FIG. 3. The inverter unit 4 has at least two solid state switches 3a, 3b, 3c, forming an rectify switching leg for each phase a, b, c, for converting the DC input voltage into AC output voltage. The solid state switches of the inverting unit 4 can be one of the possible known kinds—e.g. transistors, thyristors etc.

The converter control unit 5 is a computer device, having a data acquisition module 9 for receiving and processing input signals such as: current Iₐ, I_{b}, I_{c}, measured by the sensors 10 mounted on power supply lines a, b, c, and a voltage U_{DC} of DC link unit 3, connected to the circuit 7. The converter control unit 5 is also equipped with an output module 11 for generating switching signals for solid switches 2a, 2b, 2c of the rectifying unit 2 and for solid switches 3a, 3b, 3c of the inverting unit 3. The converter control unit 5 is also equipped with an alarm generating module 12, for comparing the initial capacitance Cᵢₙₜ and total capacitance C, and for generating alarm if certain condition is met. The DC link monitoring unit 6 is a computer device, having processing unit 13 for receiving and processing input signals such as: current Iₐ, I_{b}, I_{c} and a voltage U_{DC} of DC link unit 3, and signals from switches 2a, 2b, 2c, 3a, 3b, 3c, The DC link monitoring unit 6 is equipped with the calculation module 14 for calculating an indicator of ESR (Equivalent Series Resistance) and for calculation a total capacitance C of the DC link unit 3.

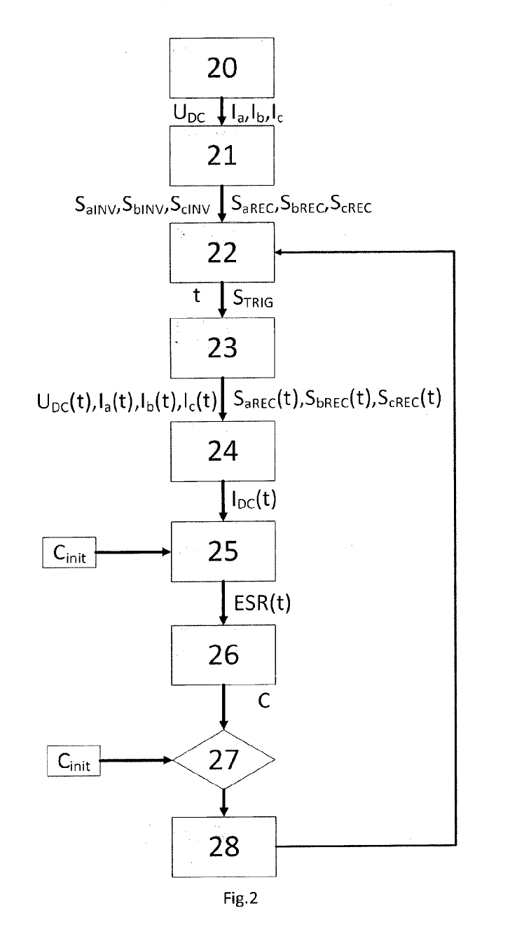

The inventive method is implemented according to the following steps 20-28 presented in FIG. 2.

Step 20

Checking if there is Cinit value provided by the user.

Measuring a DC link voltage U_{DC} by the DC link voltage measuring device 8 and measuring current Iₐ, I_{b}, I_{c} of three phase power supply lines a, b, c, by the sensors 10.

Step 21

Calculation inverter switching signals S_{aINV}, S_{bINV}, S_{cINV} of the inverter unit 3 and rectifier switching signals S_{aREC}, S_{bREC}, S_{cREC} of the rectifier unit 2 in the converter control unit 5, using known control methods for such calculation e.g. field oriented control method, scalar control method, direct torque control method, and sending calculated data to the rectifier unit 2, the inverter unit 3 and DC link monitoring unit 6. The calculation is realized in the converter control unit 5. The switching signals can take the following values, according to the formulae's:

$${S}_{aREC} = \{ \begin{matrix}1 , \\ 0\end{matrix} ; {S}_{bREC} = \{ \begin{matrix}1 , \\ 0\end{matrix} ; {S}_{cREC} = \{ \begin{matrix}1 , \\ 0\end{matrix} \\ {S}_{aINV} = \{ \begin{matrix}1 , \\ 0\end{matrix} ; {S}_{bINV} = \{ \begin{matrix}1 , \\ 0\end{matrix} ; {S}_{cINV} = \{ \begin{matrix}1 , \\ 0\end{matrix} \qquad ( 1 )$$

Step 22

Generating a trigger signal S_{TRIG} by comparison each individual switching signal with all remaining switching signals and when S_{aINV}==S_{bINV}==S_{cINV} then the trigger signal S_{TRIG} has a value equal to 1.

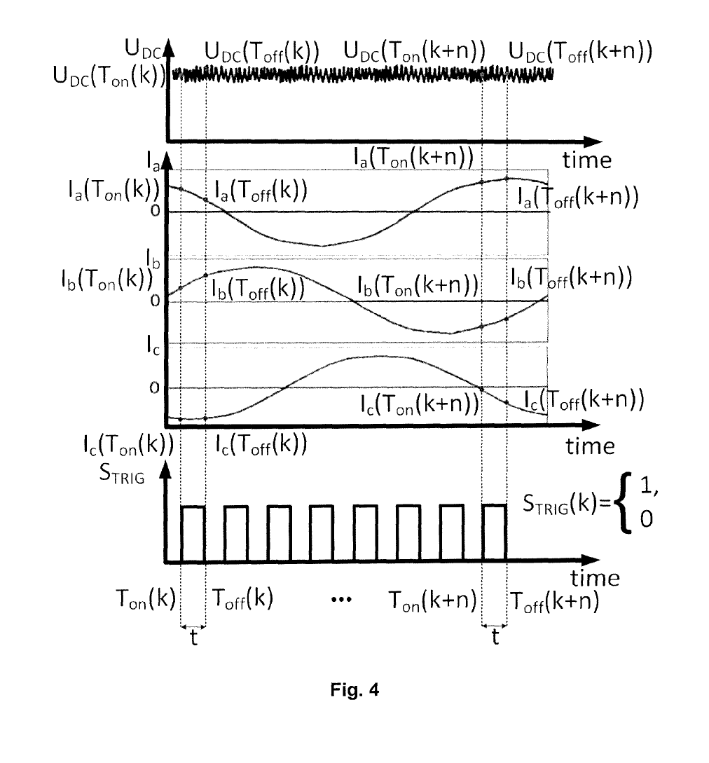

Determination of triggered time duration t for the trigger signal S_{TRIG} and indicate measured current Iₐ, I_{b}, I_{c} in the time t as Iₐ(t), I_{b}(t), I_{c}(t), where triggered time duration t is defined as the time between start Tₒₙ and stop T_{off} of the trigger signal S_{TRIG}, where k-n are consecutive number of triggered time duration t, what is presented in the FIG. 4 and described according to the formulae:

Tₒₙ(k)<t<T_{off}(k) . . . Tₒₙ(k+n)<t<T_{off}(k+n) (2)

Step 23

Determination switching signals S_{aREC}, S_{bREC}, S_{cREC} of the rectifying unit 2 from the converter control unit 5 at the triggered time t as S_{aREC}(t), S_{bREC}(t), S_{cREC}(t) and determination of the DC link voltage U_{dc} and current Iₐ, I_{b}, I_{c} of three phase power supply lines a, b, c at the triggered time t as U_{dc}(t), Iₐ(t), I_{b}(t), I_{c}(t).

Step 24

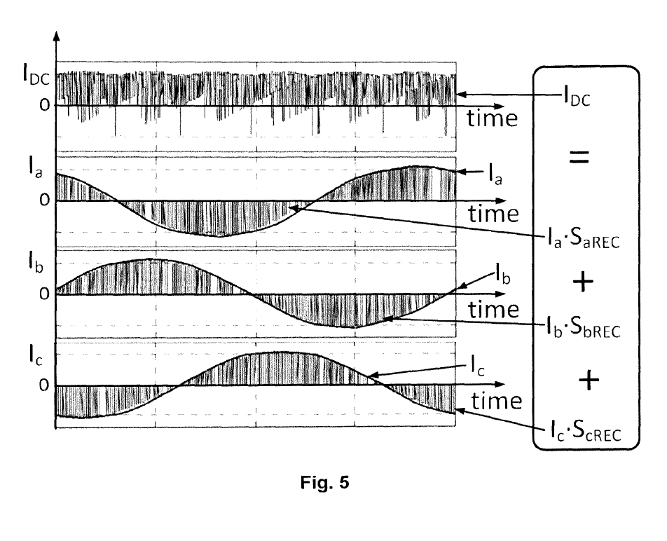

Reconstructing the DC link current by multiplying phase current Iₐ(t), I_{b}(t), I_{c}(t) at the triggered time t by corresponding rectify switching signal S_{aREC}(t), S_{bREC}(t), S_{cREC}(t) at the triggered time t and making a sum of all results what is presented in FIG. 5 and described according to the formulae:

I_{DC}(t)=S_{aREC}(t)·Iₐ(t)+S_{bREC}(t)·I_{b}(t)+S_{cREC}(t)·I_{c}(t) (3)
where:
Iₐ(t)—is a measured current for phase a, at the triggered time t,
I_{b}(t),—is a measured current for phase b, at the triggered time t,
I_{c}(t),—is a measured current for phase c, at the triggered time t,
S_{aREC}(t),—is a value of switching signal of the rectifying unit for phase a, at the triggered time t,
S_{bREC}(t),—is a value of switching signal of the rectifying unit for phase b, at the triggered time t,
S_{bREC}(t),—is a value of switching signal of the rectifying unit for phase c, at the triggered time t.

Step 25

Calculating an indicator of an Equivalent Series Resistance (ESR) in monitoring unit 6, which requires the DC link voltage U_{DC} measured voltage and I_{DC} current obtained using equation 3 and is initial DC link capacitance provided by the user, according to the formula:

$$ESR ( t ) = {\int }_{{T}_{on}}^{{T}_{off}} \frac{\frac{d {U}_{D C} ( t )}{d t} - \frac{{I}_{D C} ( t )}{{C}_{init}}}{\frac{d {I}_{D C} ( t )}{d t}} d t \qquad ( 4 )$$

where:
U_{DC}(t)—is measured DC link voltage at the triggered time t,
Cᵢₙᵢₜ—is initial DC link capacitance stored in the converter control unit 5,
I_{DC}(t)—is calculated DC link current, at the triggered time t,
Tₒₙ—is the start time of the triggered signal S_{TRIG},
T_{off}—is the stop time of the triggered signal S_{TRIG}.

Step 26

Calculating the total DC link capacitance C (in percent's), which requires using I_{DC} current obtained using equation 3, ESR indicator obtained using equation 4 and measured DC link voltage, according to the formulae:

$$C [ \% ] = \frac{{( {I}_{D C} ( t ) \cdot ESR ( t ) - {U}_{D C} ( t ) )}^{2}}{{U}_{D C}^{2} ( t )} \cdot 100 \% \qquad ( 5 )$$

where:
I_{DC}(t)—is calculated reconstructed DC link current,
U_{DC}(t)—is measured DC link voltage,
ESR(t)—is calculated equivalent series resistance.

Step 27

Comparing the initial capacitance Cᵢₙᵢₜ with the calculated total capacitance C in alarm generating module 12, according to the formulae:

C[%]<kₚ·Cᵢₙᵢₜ [%] (6)

Where the value of k is a threshold value given by user depended on a nominal power of the converter, for example for the converter of 1 MW power the value of kₚ is preferably 0.7.

Step 28

Generating an alarm if the threshold value is exceeded and sending a command from alarm generating module 12 to the output module 11 where rectify switching signals S_{aREC}, S_{bREC}, S_{cREC} of rectifying unit 2 and inverter switching signals S_{aINV}, S_{bINV}, S_{cINV} of inverter unit 4, are set to 0, which signals automatically switched off the converter circuit 1. In all other situations steps 22-27 are repeated.

1.-8. (canceled)

9. A method for monitoring DC link capacitance in power converters comprises the following steps:
measuring current in each of phases a, b, c,
measuring voltage of a DC link unit and setting initial capacitance Cᵢₙₜ of the DC link unit, where the initial capacitance of the DC link unit is given by a user,
determining inverter switch states of an inverter and rectifier switch states of a rectifier for each phase a, b, c, where the switching states have a value equal to 0 or 1,
generating a trigger signal S_{TRIG} when the value of the inverter switch states of the inverter for each phase a, b, c have equal values and determining a triggered time duration t for the generated trigger signal,
determining the rectifier switch states of the rectifier unit for each phase a, b, c at the triggered time duration t and calculating current of the phase a, b, c and voltage of the DC link unit at the triggered time duration t,
reconstructing the DC link current I_{DC}(t) at the triggered time duration t using the following formulae:
I_{DC}(t)=S_{aREC}(t)·Iₐ(t)+S_{bREC}(t)·I_{b}(t)+S_{cREC}(t)·I_{c}(t)
where:
Iₐ(t)—is a measured current for phase a at the triggered time duration t,
I_{b}(t)—is a measured current for phase b at the triggered time duration t
I_{c}(t)—is a measured current for phase c at the triggered time duration t,
S_{aREC}(t)—is a value of switching signal of the rectifier unit for phase a at the triggered time duration t,
S_{bREC}(t)—is a value of switching signal of the rectifying unit for phase b at the triggered time duration t,
S_{cREC}(t)—is a value of switching signal of the rectifier unit for phase c at the triggered time duration t,
calculating an indicator ERS (Equivalent Series Resistance) for the DC link voltage at the triggered time duration t according to the formulae:
$$ESR ( t ) = {\int }_{{T}_{on}}^{{T}_{off}} \frac{\frac{d {U}_{D C} ( t )}{d t} - \frac{{I}_{D C} ( t )}{{C}_{init}}}{\frac{d {I}_{D C} ( t )}{d t}} d t$$
where:
U_{DC}(t)—is a measured DC link voltage at the triggered time duration t,
Cᵢₙᵢₜ—is initial DC link capacitance given by the user and stored in the converter control unit,
I_{DC}(t)—is a reconstructed current od DC link at the triggered time duration t,
Tₒₙ—is the start time of the triggered signal S_{TRIG},
T_{off}—is the stop time of the triggered signal S_{TRIG},
calculating a total DC link capacitance C according to the formulae:
$$C [ \% ] = \frac{{( {I}_{D C} ( t ) \cdot ESR ( t ) - {U}_{D C} ( t ) )}^{2}}{{U}_{D C}^{2} ( t )} \cdot 100 \%$$
where:
I_{DC}(t)—is calculated DC link current at the triggered time duration t,
U_{DC}(t)—is measured DC link voltage at the triggered time duration t,
ESR(t)—is calculated equivalent series resistance indicator at the triggered time duration t,
comparing the value of total DC link capacitance C with the initial DC link capacitance Cᵢₙₜ and triggering an alarm when the initial DC link capacitance Cᵢₙₜ is bigger than a threshold value given by the user.

10. A system for monitoring DC link capacitance in power converter comprising a power converter circuit with a rectifying unit a DC link unit, an inverter unit which are connected with a converter control unit and with a DC monitoring unit and with means for measuring electrical parameters of the system, wherein further comprising:
means for setting initial capacitance Cᵢₙₜ of the DC link unit, where the initial capacitance of the DC link unit is given by the user in a computer device,
means for determining inverter switch states of the inverter unit and means for determining rectifier switch states of the rectifying unit for each phase a, b, c, implemented in the computer device,
means for comparing the value of inverter switch states and for generating a trigger signal S_{TRIG} when the value of the inverter switch states of the inverter unit for each phase a, b, c have an equal values, implemented in the converter control unit,
means for determining a triggered time duration t, implemented in the converter control unit,
means for determining the rectifier switch states of the rectifying unit for each phase a, b, c at the triggered time duration t and calculating current of the phase a, b, c and voltage of the DC link unit at the triggered time duration t,
means for reconstructing the DC link current at the triggered time duration t
means for calculating an indicator ERS (Equivalent Series Resistance) for the DC link unit voltage at the triggered time duration t and means for calculating a total DC link unit capacitance C,
means for comparing the value of total DC link unit capacitance C with the initial DC link capacitance Cᵢₙₜ,
means for triggering an alarm when the initial DC link capacitance Cᵢₙₜ is bigger than a threshold value given by user.

11. A system according to claim 10, wherein the converter circuit comprises solid switches connected to the switching legs of the rectifying unit and inverter unit respectively.

12. A system according to claim 11, characterized in that the solid switches have a form of diodes or transistors or thyristors.

13. A computer program for monitoring DC link capacitance in power converter system, which computer program is loadable in and executable on a data processing unit of a computer device having a form of a DC monitoring device and which computer program performs when being executed by the data processing unit of the computer device, the method according to claim 9.
